(19) United States
(12) Patent Application Publication
(10) Pub. No.: US 2026/0179215 A1
(43) Pub. Date: Jun. 25, 2026

(54) SUBSTRATE PROCESSING APPARATUS AND SUBSTRATE PROCESSING METHOD

(71) Applicant: Tokyo Electron Limited, Tokyo (JP)

(72) Inventor: Akinori TANAKA, Koshi City (JP)

(73) Assignee: Tokyo Electron Limited, Tokyo (JP)

(21) Appl. No.: 19/430,322

(22) Filed: Dec. 23, 2025

(30) Foreign Application Priority Data
Dec. 24, 2024 (JP) 2024-227277

(51) Int. Cl. G06T 7/00; G06T 7/73; H04N 23/73; H04N 23/74; H04N 23/75

(52) U.S. Cl. CPC G06T 7/001; G06T 7/0008; G06T 7/74; H04N 23/73; H04N 23/74; H04N 23/75; G06T 2207/10144; G06T 2207/10148; G06T 2207/10152; G06T 2207/30148

(57) ABSTRACT

A substrate processing apparatus includes a rotating/holding device to hold and rotate a substrate having a cutout portion; an imaging device configured to image the substrate held by the rotating/holding device; and a controller circuitry to perform acquiring multiple captured images including an entire substrate with the imaging device by imaging, with the substrate held by the rotating/holding device being stopped, the entire substrate multiple times at a same imaging position while varying imaging parameters; setting, for the multiple captured images, processing regions in different areas depending on the imaging parameters; and detecting a position of the cutout portion of the substrate by image-processing the respective processing regions of the multiple captured images.

### CROSS-REFERENCE TO RELATED APPLICATION

This application claims the benefit of Japanese Patent Application No. 2024-227277 filed on Dec. 24, 2024, the entire disclosures of which are incorporated herein by reference.

### TECHNICAL FIELD

The various aspects and embodiments described herein pertain generally to a substrate processing apparatus and a substrate processing method.

### BACKGROUND

Currently, in manufacturing a semiconductor device by microfabrication of a substrate (for example, a semiconductor wafer), there is known a substrate processing system that processes the substrate by discharging various kinds of processing liquids onto the substrate while rotating the substrate held by a holder (see, for example, Patent Document 1).
Patent Document 1: Japanese Patent Laid-open Publication No. 2014-025859

### SUMMARY

In one exemplary embodiment, a substrate processing apparatus includes a rotating/holding device configured to hold and rotate a substrate having a cutout portion; an imaging device configured to image the substrate held by the rotating/holding device; and a controller. The controller is configured to perform: acquiring multiple captured images including an entire substrate with the imaging device by imaging, with the substrate held by the rotating/holding device being stopped, the entire substrate multiple times at a same imaging position while varying imaging parameters; setting, for the multiple captured images, processing regions in different areas depending on the imaging parameters; and detecting a position of the cutout portion of the substrate by image-processing the respective processing regions of the multiple captured images.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a plan view schematically illustrating an example of a substrate processing system;

FIG. 2 is a cross sectional view schematically illustrating an example of a liquid processing device, depicting a state where a substrate is located at a lowered position;

FIG. 3 is a cross sectional view schematically illustrating the example of the liquid processing device, depicting a state where the substrate is located at a raised position;

FIG. 4 is a block diagram illustrating an example of main components of the substrate processing system;

FIG. 5 is a schematic diagram illustrating a hardware configuration of a controller;

FIG. 6 is a flowchart illustrating an example of a substrate processing;

FIG. 7 is a flowchart illustrating an example of a cutout portion detection processing;

FIG. 8 is a flowchart illustrating an example of a positional deviation detection processing;

FIG. 9A to FIG. 9C are diagrams illustrating an example of three images captured when an imaging device images the entire substrate three times while varying imaging parameters;

FIG. 10A is a diagram showing an example of a corrected image in which distortion aberration has been corrected, and FIG. 10B is a diagram illustrating a corrected image in which an outer periphery of the substrate has been corrected to become a substantially perfect circle;

FIG. 11A shows a diagram showing an example of a corrected image after being subjected to polar coordinate transformation, FIG. 11B is a diagram showing an example of an extracted image after being subjected to edge extraction, FIG. 11C is a diagram showing an example of a binarized image after being subjected to binarization, FIG. 11D is a diagram showing an example of a complemented image after being subjected to edge completion, and FIG. 11E is a diagram showing an example of the complemented image on which a substrate contour line, an imaginary line segment, and a cutout portion contour line are drawn; and

FIG. 12 is a diagram illustrating an example of a composite image obtained by compositing respective processing regions of multiple captured images into one.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

In the following description, same parts or parts having same functions will be assigned same reference numerals, and redundant descriptions thereof will be omitted. Further, in the present specification, up, down, right, and left of the drawings are defined with reference to the orientation of the reference numerals shown in the drawings.

### [Substrate Processing System]

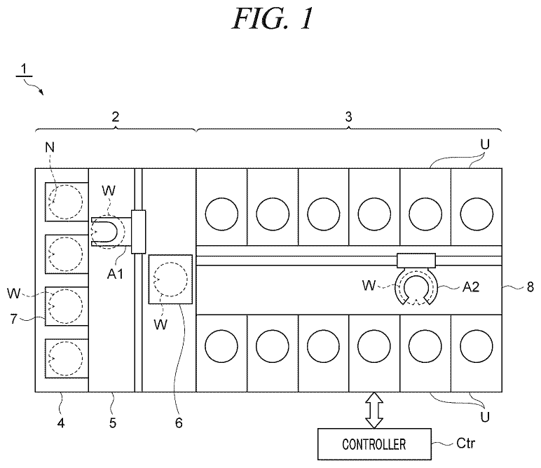

First, referring to FIG. 1, a substrate processing system 1 (substrate processing apparatus) configured to process a substrate W will be explained. The substrate processing system 1 includes a carry-in/out station 2, a processing station 3, and a controller Ctr (control device). The carry-in/out station 2 and the processing station 3 may be arranged in a row in a horizontal direction, for example.

The substrate W may be of a circular plate shape, or may be of a plate shape other than a circle, such as a polygon. The substrate W may have a cutout portion N which is partially cut out. The cutout portion N may be, by way of example, a notch (a groove of a U-shape, a V-shape, etc.), or a linear portion (so-called orientation flat) that extends linearly. The substrate W may be, by way of non-limiting example, a semiconductor substrate (silicon wafer), a glass substrate, a mask substrate, a flat panel display (FPD) substrate, or any of various other types of substrates. The substrate W may have a diameter of, e.g., about 200 mm to about 450 mm.

The carry-in/out station 2 includes a placement section 4, a carry-in/out section 5, and a shelf module 6. The placement section 4 includes a plurality of placement tables arranged in a width direction (up-and-down direction in FIG. 1). Each placement table is configured to place a carrier 7 thereon. The carrier 7 is configured to accommodate at least one substrate W in a sealed state. The carrier 7 includes an opening/closing door through which the substrate W is carried in and out.

The carry-in/out section 5 is disposed adjacent to the placement section 4 in the direction in which the carry-in/out station 2 and the processing station 3 are arranged (left-and-right direction in FIG. 1). The carry-in/out section 5 includes an opening/closing door for the placement section 4. With the carrier 7 placed on the placement section 4, the opening/closing door of the carrier 7 and the opening/closing door of the carry-in/out section 5 are both opened, thus allowing the inside of the carry-in/out section 5 and the inside of the carrier 7 to communicate with each other.

The carry-in/out section 5 has a transfer arm A1 and the shelf module 6 therein. The transfer arm A1 is configured to be movable horizontally in the width direction of the carry-in/out section 5, movable up and down in a vertical direction, and pivotable around a vertical axis. The transfer arm A1 serves to take out the substrate W from the carrier 7 and hand it over to the shelf module 6, and also serves to receive the substrate W from the shelf module 6 and return it back into the carrier 7. The shelf module 6 is located near the processing station 3, and is configured to accommodate the substrate W therein.

The processing station 3 includes a transfer section 8 and a plurality of liquid processing devices U. For example, the transfer section 8 extends horizontally in the direction in which the carry-in/out station 2 and the processing station 3 are arranged (left-and-right direction in FIG. 1). The transfer section 8 incorporates a transfer arm A2 therein. The transfer arm A2 is configured to be movable horizontally in a lengthwise direction of the transfer section 8, movable up and down in a vertical direction, and pivotable around a vertical axis. The transfer arm A2 serves to take out the substrate W from the shelf module 6 and hand it over to the liquid processing device U, and also serves to receive the substrate W from the liquid processing device U and return it back into the shelf module 6.

The plurality of liquid processing devices U are arranged in a row along a lengthwise direction (left-and-right direction in FIG. 1) of the transfer section 8 at both sides of the transfer section 8. A configuration of the liquid processing devices U will be described later.

The controller Ctr is configured to control the substrate processing system 1 partially or in an overall manner, as will be described later in detail.

### [Liquid Processing Device]

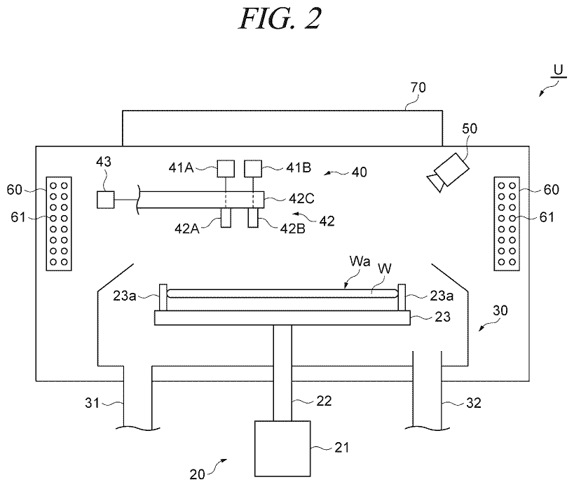

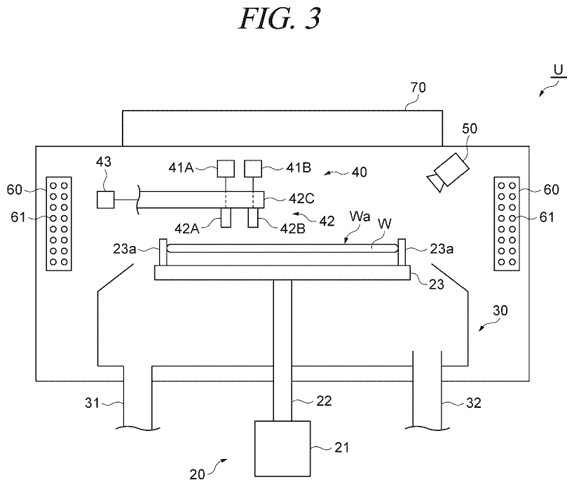

Now, the liquid processing device U will be explained with reference to FIG. 2 and FIG. 3. The liquid processing device U includes a housing 10, a driver 20 (a rotating/holding device and an elevating device), a cup 30, a supply 40, an imaging device 50, at least one illumination device 60, and a blower 70.

The housing 10 is configured such that the substrate W is carried into and carried out of it. A carry-in/out opening is formed in a sidewall of housing 10. The substrate W is carried into the housing 10 and carried out from the housing 10 to the outside through this carry-in/out opening by the transfer arm A2.

The driver 20 includes a driving source 21, a shaft 22, and a holder 23. The driving source 21 is operated based on an operation signal from the controller Ctr to rotate the shaft 22 and also, to move the shaft 22 up and down. The driving source 21 is a driving source such as, but not limited to, an electric motor or an electric actuator.

The holder 23 is of, for example, a circular plate shape, and is provided on a leading end of the shaft 22. By the operation of the driving source 21, the holder 23 is rotated via the shaft 22 and is also moved up and down via the shaft 22.

Multiple holding members 23a protruding upwards are provided on a top surface of the holder 23. The multiple holding members 23a are configured to move in a radial direction of the holder 23 to hold an outer edge of the substrate. That is, the substrate W is held above the top surface of the holder 23 in a substantially horizontal manner by the multiple holding members 23a.

As described above, the driver 20 is configured to rotate the substrate W around a central axis (rotation axis) perpendicular to a top surface Wa of the substrate W, while holding the substrate W substantially in a horizontal manner. The driver 20 is also configured such that the driving source 21 raises and lowers the shaft 22, thereby allowing the holder 23 to be moved up and down between a lowered position (see FIG. 2) and a raised position (see FIG. 3). As illustrated in FIG. 2, at the lowered position, the substrate W held by the multiple holding members 23a is located inside the cup 30. On the other hand, at the raised position, the substrate W held by the multiple holding members 23a is located above the cup 30, as illustrated in FIG. 3.

As shown in FIG. 2, the cup 30 is provided so as to surround the holder 23 from the outside thereof. The cup 30 is configured to collect a processing liquid (for example, a chemical liquid L1 and a cleaning liquid L2 to be described later) that is scattered around from the outer edge of the substrate W when the substrate W is held and rotated by the driver 20. A drain port 31 and an exhaust port 32 are provided in a bottom of the cup 30.

The drain port 31 is configured to drain the processing liquid collected by the cup 30 to the outside of the liquid processing device U. The exhaust port 32 is configured to exhaust a downward flow formed around the substrate W by the blower 70 to the outside of the liquid processing device U. The downward flow includes a gas generated around the substrate W as the substrate W is processed by the processing liquid.

The supply 40 is configured to supply the processing liquid (the chemical liquid L1 and the cleaning liquid L2) to the top surface Wa of the substrate W. The supply 40 includes supply mechanisms 41A and 41B, a nozzle assembly 42, and a driving source 43.

The supply mechanism 41A is operated based on an operation signal from the controller Ctr, and is configured to send the chemical liquid L1 stored in a container by a liquid delivery mechanism such as a pump. The chemical liquid L1 may contain, for example, an alkaline or acidic chemical liquid for a chemical treatment (for example, removal of contaminants and foreign matters, etching, etc.). The alkaline chemical liquid may contain, by way of non-limiting example, a SC-1 solution (a mixed solution of ammonia, hydrogen peroxide, and pure water). The acidic solution may include, by way of non-limiting example, a SC-2 solution (a mixed solution of chloric acid, hydrogen peroxide, and pure water), SPM (a mixed solution of sulfuric acid and hydrogen peroxide), a HF/HNO₃ solution (a mixed solution of hydrofluoric acid and nitric acid), or the like.

The supply mechanism 41B is operated based on an operation signal from the controller Ctr, and is configured to send the cleaning liquid L2 stored in a container by a liquid delivery mechanism such as a pump. The cleaning liquid L2 may include, for example, pure water (deionized water (DIW)), ozone water, carbonated water (CO₂ water), ammonia water, or the like.

The nozzle assembly 42 is configured to discharge the chemical liquid L1 and the cleaning liquid L2 supplied from the supply mechanisms 41A and 41B, respectively, onto the top surface Wa of the substrate W. The nozzle assembly 42 includes nozzles 42A and 42B, and an arm 42C. The nozzle 42A is connected via a pipeline to the container that stores the chemical liquid L1. The nozzle 42B is connected via a pipeline to the container that stores the cleaning liquid L2. The arm 42C holds the nozzles 42A and 42B.

The driving source 43 is configured to move the arm 42C in a height direction and a horizontal direction based on a signal from the controller Ctr.

The imaging device 50 is operated based on an operation signal from the controller Ctr, and is configured to image the entire top surface Wa of the substrate W held by the multiple holding members 23a. Inside the housing 10, the imaging device 50 is located at a position where it does not overlap the substrate W held by the multiple holding members 23a, when viewed from above. The imaging device 50 may be mounted directly to a wall surface of the housing 10, or may be mounted indirectly to the housing 10 with a support member or the like therebetween.

The at least one illumination device 60 is operated based on an operation signal from the controller Ctr, and is configured to illuminate the substrate W when the imaging device 50 is imaging the substrate W. The at least one illumination device 60 may be mounted to an inner wall surface (for example, a side wall portion, a ceiling portion, etc.) of the housing 10. The liquid processing device U may include multiple illumination devices 60. The illumination device 60 is composed of an assembly of multiple light sources 61. The illumination device 60 may be, by way of example, an LED module in which multiple LEDs are arranged.

The blower 70 is disposed at a ceiling portion of the housing 10 to be located above the driver 20 and the cup 30. When viewed from above, the blower 70 completely covers the substrate W held by the multiple holding members 23a. The blower 70 is operated based on an operation signal from the controller Ctr, and is configured to generate a downward flow heading toward the top surface Wa of the substrate W held by the multiple holding members 23a.

### [Controller]

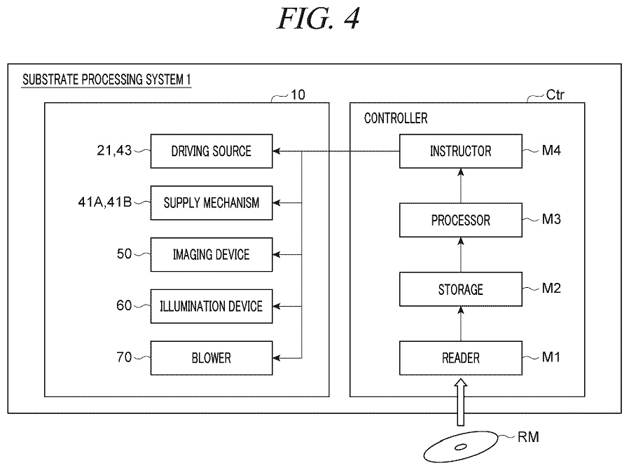

As illustrated in FIG. 4, the controller Ctr has, as functional modules, a reader M1, a storage M2, a processor M3, and an instructor M4. These functional modules are merely a convenient division of the functions of the controller Ctr into multiple modules, and do not necessarily imply that the hardware constituting the controller Ctr is divided into these modules. Each functional module is not limited to being implemented by execution of a program, and it may also be implemented by a dedicated electrical circuit (e.g., a logic circuit) or an integrated circuit (application specific integrated circuit (ASIC)) that integrates such circuits. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium, such as a CD-ROM or DVD, and/or the memory of a FPGA or ASIC.

The reader M1 is configured to read a program from a computer-readable recording medium RM. The recording medium RM records thereon a program for operating the individual components of the substrate processing system 1 (the driving sources 21 and 43, the supply mechanisms 41A and 41B, the imaging device 50, the illumination device 60, the blower 70, etc.). The recording medium RM may be, by way of non-limiting example, a semiconductor memory, an optical recording disk, a magnetic recording disk, or a magneto-optical recording disk. The recording medium RM may be embedded in the substrate processing system 1 or may be provided separately from the substrate processing system 1.

The storage M2 is configured to store various types of data. The storage M2 may store, for example, the program read from the recording medium RM in the reader M1, setting data input from an operator via an external input device, and so forth.

The processor M3 is configured to process various types of data. For example, the processor M3 may be configured to generate operation signals for operating the individual components of the substrate processing system 1 based on the various data stored in the storage M2.

The instructor M4 is configured to transmit the operation signals generated by the processor M3 to the individual components of the substrate processing system 1.

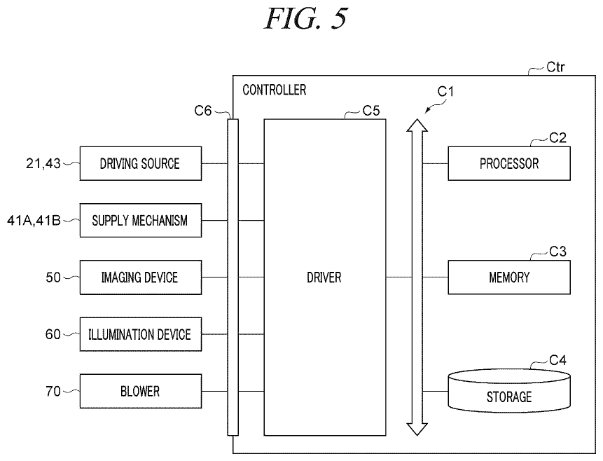

The hardware of the controller Ctr may be composed of, for example, one or more control computers. The controller Ctr may include, for example, a circuit C1 shown in FIG. 5 as its hardware configuration. The circuit C1 may be composed of electrical circuit elements (circuitry). The circuit C1 may include, for example, a processor C2, a memory C3 (storage), a storage C4 (storage), a driver C5, and an input/output port C6. The processor C2 executes a program in cooperation with at least one of the memory C3 and the storage C4 and carries out an input/output of signals via the input/output port C6, thereby configuring each of the functional modules described above. The memory C3 and the storage C4 function as the storage M2. The driver C5 is a circuit that operates the individual components of the substrate processing system 1. The input/output port C6 performs an input/output of signals between the driver C5 and the individual components of substrate processing system 1.

The substrate processing system 1 may include one controller Ctr or a controller group (control device) composed of multiple controllers Ctr. In the latter case, each of the aforementioned functional modules may be implemented by a single controller Ctr, or by a combination of two or more controllers Ctr. If the controller Ctr is composed of multiple computers (circuits C1), each of the aforementioned functional modules may be implemented by a single computer (circuit C1) or by a combination of two or more computers (circuits C1). The controller Ctr may include multiple processors C2. In this case, each of the aforementioned functional modules may be implemented by a single processor C2 or by a combination of two or more processors C2.

### [Substrate Processing Method]

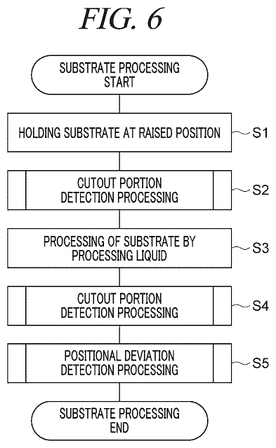

Now, a processing of the substrate W will be explained with reference to FIG. 6 to FIG. 11E. First, the controller Ctr instructs the transfer arms A1 and A2 to take out one substrate W from the carrier 7 and transfer it toward one of the liquid processing devices U. Next, in that liquid processing device U, the controller Ctr instructs the driving source 21 to raise the holder 23 to the raised position (see FIG. 3). Then, the controller Ctr instructs the transfer arm A2 to carry the substrate W into the housing 10, allowing the substrate W to be held by the multiple holding members 23a (see a process S1 in FIG. 6).

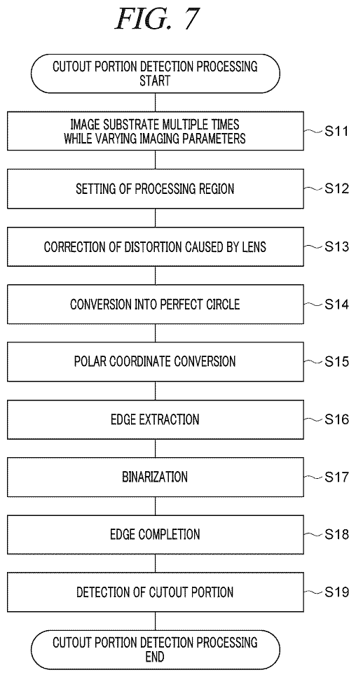

Thereafter, the controller Ctr performs a detection processing for the cutout portion N of the substrate W (see a process S2 in FIG. 6). The detection processing for the cutout portion N will be explained below with reference to FIG. 7.

First, with the holder 23 located at the raised position and the substrate W being stopped, the controller Ctr instructs the imaging device 50 and the illumination device 60 to image the entire substrate W multiple times, while varying imaging parameters (see a process S11 in FIG. 7). As a result, multiple captured images I1 including the entire substrate W are acquired by the imaging device 50, and these multiple captured images are then transmitted from the imaging device 50 to the controller Ctr. At this time, since the imaging device 50 is fixed to the housing 10, the imaging position of the substrate W by the imaging device 50 does not change. Furthermore, since the imaging device 50 is positioned so as not to overlap the substrate W held by the multiple holding members 23a when viewed from above, the outer periphery of the substrate W in each captured image is approximately elliptical.

Here, the imaging parameters may include, by way of example, luminance of the illumination device 60, illumination time of the illumination device 60, a focal position of the imaging device 50, an ISO sensitivity of the imaging device 50, an exposure of the imaging device 50, and so forth. If the liquid processing device U includes multiple illumination devices 60, the imaging parameters may include, by way of example, luminance of each illumination device 60, illumination time of each illumination device 60, a position of the illumination device 60 that provides the illumination among the multiple illumination devices 60, a focal position of the imaging device 50, an ISO sensitivity of the imaging device 50, an exposure of the imaging device 50, and the like. When the illumination device 60 is composed of an assembly of multiple light sources 61, the imaging parameters may include, by way of example, luminance of the illumination device 60, illumination time of the illumination device 60, a position of the light source 61 that provides the illumination among the multiple light sources 61, a focal position of the imaging device 50, an ISO sensitivity of the imaging device 50, an exposure of the imaging device 50, and the like. By setting these imaging parameters, a clearer image can be obtained in each processing region R of the multiple captured images I1.

Next, different processing regions R are set for the respective captured images I1 according to the imaging parameters (see a process S12 in FIG. 7). For example, the different processing regions R may be set for relatively clear regions in the respective captured image I1.

Each processing region R may be determined in advance by imaging a test substrate W multiple times while varying the imaging parameters. Alternatively, each processing region R may be determined each time the captured image I1 is acquired by having the controller Ctr to detect a relatively clear region in each captured image I1. Furthermore, the setting of the processing regions R may be performed after the process S11 and before a process S15 in FIG. 7. That is, the different processing regions R may be set for respective corrected images I2 to be described later, or the different processing regions R may be set for respective corrected images I3 to be described later.

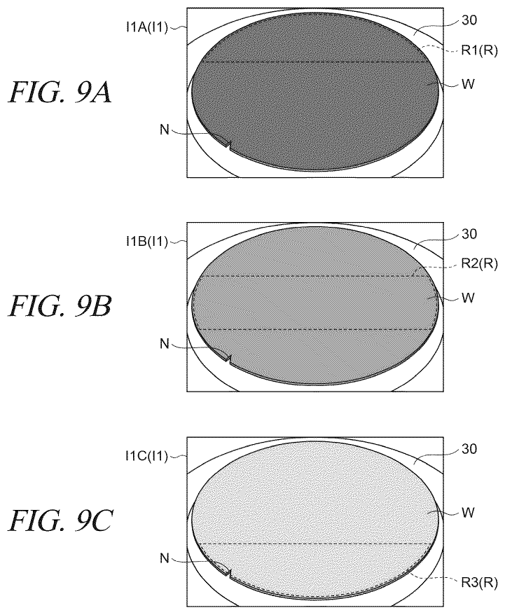

FIG. 9A to FIG. 9C show examples of three captured images I1A to I1C obtained when the imaging device 50 images the entire substrate W three times while varying the imaging parameters. As for the imaging parameters for the captured image I1A, the illumination time by the illumination device 60 may be set to be shorter than that for the other images I1B and I1C. In this case, an inner region in the captured image I1A becomes relatively clear, for example. Therefore, a processing region R1 is set in the inner region of the captured image I1A. For example, the processing region R1 may be in the range of 100° to 260° when the frontmost position of the substrate W in the captured image 11A is set to 0°.

As for the imaging parameters for the captured image I1B, the illumination time by the illumination device 60 may be set to be longer than that for the captured image I1A and shorter than that for the captured image I1C. In this case, a central region in the captured image I1B appears relatively clear, for example. Therefore, a processing region R2 is set in the central region of the captured image I1B. For example, the processing region R2 may be in the range of 50° to 100° and 260° to 310° when the frontmost position of the substrate W in the captured image I1B is set to 0°.

As for the imaging parameters for the captured image I1C, the illumination time by the illumination device 60 may be set to be longer than that for the other captured images I1A and I1B. In this case, a front region in the captured image I1C appears relatively clear, for example. Therefore, a processing region R3 is set in the front region of the captured image I1C. For example, the processing region R3 may be in the range of 0° to 50° and 310° to 360° when the frontmost position of the substrate W in the captured image I1C is set to 0°.

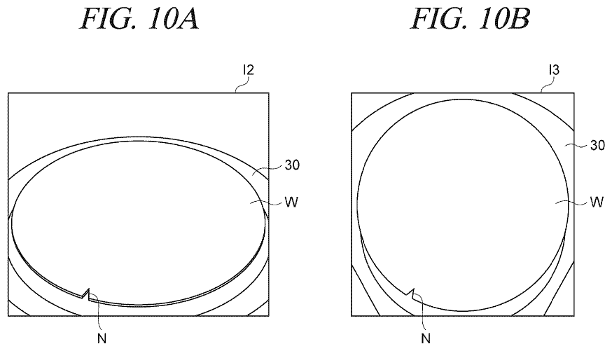

Subsequently, for the multiple captured images I1, the controller Ctr corrects distortion (distortion aberration) caused by a lens (for example, a wide-angle lens) of the imaging device 50 (see a process S13 in FIG. 7). The controller Ctr may correct the distortion aberration by performing an operation using a known method based on, for example, optical characteristics of the lens of the imaging device 50, an imaging distance, and so forth. As a result, multiple corrected images 12, which are corrections of the multiple captured images I1, are obtained. FIG. 10A shows an example of the corrected image I2 with its distortion aberration corrected.

Here, if the cutout portion N exists at an inner portion of the outer periphery of the substrate W in the corrected image I2, the cutout portion N appear relatively small, whereas if the cutout portion N exists at a front portion of the outer periphery of the substrate W in the corrected image I2, the cutout portion N appears relatively large. Thus, the controller Ctr corrects each corrected image I2 by a known method so that the outer periphery of the substrate W in the corrected image I2 becomes a substantially perfect circle (see a process S14 in FIG. 7). As a result, multiple corrected images I3, which are corrections of the multiple corrected images I2, are obtained. As a consequence, regardless of the location of the cutout portion N on the outer periphery of the substrate W in the corrected image I2, the size of the cutout portion N becomes substantially uniform. FIG. 10B shows an example of the corrected image I3 in which the outer periphery of the substrate W has been corrected so that it forms a substantially perfect circle.

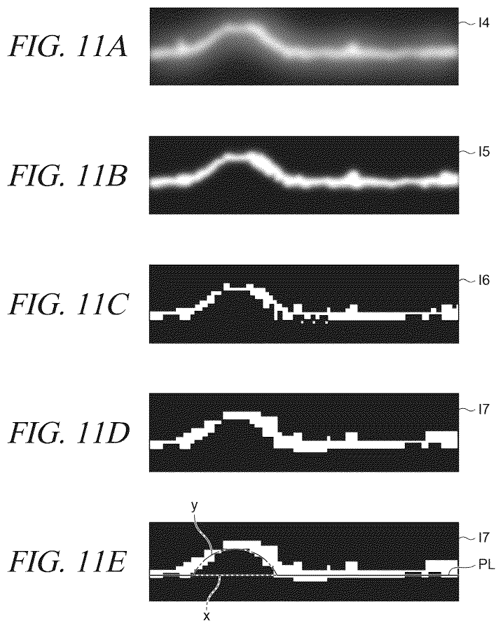

Next, the controller Ctr performs polar coordinate transformation for the processing region R set in each corrected image I3 (see a process S15 in FIG. 7). That is, the controller Ctr corrects each corrected image I3 by a known method so that the contour of the substrate W in the processing region R set in the corrected image I3 becomes a straight line. As a result, multiple corrected images 14, which are corrections of the multiple corrected images I3, are obtained. FIG. 11A shows an example of the corrected image I4 after being subjected to the polar coordinate transformation. As shown in FIG. 11A, each corrected image I4 may be an image obtained by extracting only the vicinity of the contour of the substrate W. In this case, since the center-side portion of the substrate W is not subjected to the image-processing, a reflection appearing on the top surface Wa of the substrate W is excluded from a target of the image-processing, which enables a reduction in a computational load.

Next, the controller Ctr performs edge extraction on each corrected image I4 (see a process S16 in FIG. 7). By way of example, by using a known method, the controller Ctr detects, based on a luminance value of each corrected image I4, a portion in each corrected image I4 where brightness changes subtly. As a result, multiple extracted images I5, which have undergone the edge extraction from the multiple corrected images I4, are obtained. FIG. 11B shows an example of the extracted image I5 after being subjected to the edge extraction processing. Here, each corrected image I4 may also be subjected to noise reduction by a known method before each corrected image 14 is subjected to the edge extraction processing.

Subsequently, the controller Ctr binarizes each extracted image I5 by a known method (see a process S17 in FIG. 7). As a result, multiple binarized images I6, which are binarized from the extracted images I5, are obtained. FIG. 11C shows an example of the binarized image I6.

Thereafter, the controller Ctr complements edges in each binarized image I6 by using a known method (for example, a morphological operation) (see a process S18 in FIG. 7). As a result, the boundaries between white and block regions in the multiple binarized images I6 are adjusted. FIG. 11D shows an example of a complemented image I7 after being subjected to the edge completion.

Next, the controller Ctr extracts a contour line corresponding to the outer edge of the substrate W in each complemented image I7. Specifically, since the outer edge of the substrate W in each complemented image I7 is linear, the controller Ctr extracts, as a substrate contour line PL, a portion where the boundary between the white and black regions in each complemented image I7 is linear. FIG. 11E shows an example of the complemented image I7 on which the linear substrate contour line PL (solid line in FIG. 11E) is drawn.

Thereafter, the controller Ctr extracts a candidate for the cutout portion N from each complemented image I7. Specifically, the controller Ctr detects, as the candidate for the cutout portion N, a portion in the complemented image I7 where the substrate counter line PL is interrupted. FIG. 11E shows an example of the complemented image I7 where an imaginary line segment x (dashed line in FIG. 11E) is drawn on the portion where the substrate contour line PL is interrupted.

Next, the controller Ctr extracts, as a cutout counter line y, an arc-shaped curve that fits the contour of a mountain-shaped portion protruding from the imaginary line segment x in each complemented image I7. FIG. 11E shows an example of the complemented image I7 in which the cutout contour line y (a dashed dotted line in FIG. 11E) is drawn.

Next, the controller Ctr calculates the length of the imaginary line segment x, the length of the cutout contour line y, the ratio of the length of the cutout contour line y to the imaginary line segment x (contour line ratio), and the area of a region surrounded by the imaginary line segment x and the cutout contour line y (the area of the candidate for cutout portion N). Then, the controller Ctr determines whether the candidate for the cutout portion N is actually the cutout portion N based on at least one of the length of the imaginary line segment x, the contour line ratio, and the area of the candidate for the cutout portion N, thereby detecting the cutout portion N (see a process S19 in FIG. 7). The controller Ctr may determine whether the candidate for the cutout portion N is actually the cutout portion N by, for example, comparing at least one of the length of the imaginary line segment x, the contour line ratio, and the area of the candidate for the cutout portion N with previously measured parameters of the cutout portion N of the substrate W.

By the above-described detection of the cutout portion N, it can be detected, before the substrate W is processed with the processing liquid, where the cutout portion N is located on the outer edge of the substrate W held by the multiple holding members 23a.

Next, referring back to FIG. 6, the substrate W is processed with the processing liquid (the chemical liquid L1 and the cleaning liquid L2) (see the process S3 of FIG. 6). Specifically, the controller Ctr instructs the driving source 21 to lower the holder 23 to the lowered position (see FIG. 2). Next, the controller Ctr instructs the driving source 21 to rotate the holder 23 at a preset rotational speed. Thereafter, the controller Ctr instructs the power source 43 to operate the arm 42C so that the nozzles 42A and 42B are positioned above the central portion of the substrate W.

Then, the controller Ctr instructs the supply mechanism 41A to supply the chemical liquid L1 to the top surface Wa of the substrate W being rotated, and then instructs the supply mechanism 41B to supply the cleaning liquid L2 to the top surface Wa of the substrate W being rotated. As a result, the substrate W is processed by the processing liquid.

Next, in the one liquid processing devices U, the controller Ctr instructs the driving source 21 to raise the holder 23 to the raised position (see FIG. 3). Then, the controller Ctr performs the detection of the cutout portion N of the substrate W again (see the process S4 in FIG. 6). Since this detection processing for the cutout portion N is the same as the processes S11 to S19 in FIG. 7, further explanation will be omitted here. Therefore, it can be detected where the cutout portion N is located on the outer periphery of the substrate W held by the multiple holding members 23a after being processed with the processing liquid.

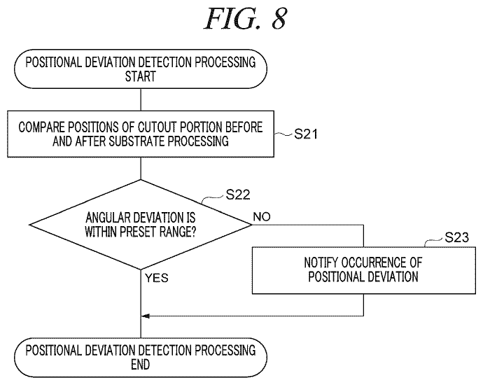

Subsequently, the controller Ctr performs detection of a positional deviation of the cutout portion N in a circumferential direction of the substrate W (see the process S5 in FIG. 6). Below, this detection processing for the cutout portion N will be explained with reference to FIG. 8.

First, the controller Ctr compares the positions of the cutout portion N before and after the processing of the substrate W by the processing liquid (see a process S21 in FIG. 8). To elaborate, the controller Ctr calculates an angular deviation between the position of the cutout portion N of the substrate W before being processed and the position of the cutout portion N of the substrate W after being processed.

Then, the controller Ctr determines whether the angular deviation is within a preset range (see a process S22 in FIG. 8). If it is determined in the process S22 of FIG. 8 that the angular deviation is within the preset range (“YES” in the process S22 in FIG. 8), the controller Ctr makes a determination that there is no positional deviation of the cutout portion N before and after the processing of the substrate W, and terminates the positional deviation detection processing.

On the other hand, if it is determined in the process S22 of FIG. 8 that the angular deviation is not within the preset range (“NO” in the process S22 in FIG. 8), the controller Ctr notifies an operator via a non-illustrated notifying device that the positional deviation of the cutout portion N has occurred (see a process S23 in FIG. 8). The notification by the notifying device may be in the form of, e.g., sound or light, or may be a display of an image, video, a text, etc. on a display.

Upon the completion of the positional deviation detection processing for the cutout portion N, the processing of the substrate W is completed.

### [Operations]

In the above-described exemplary embodiment, the entire substrate W is imaged multiple times at the same imaging position while varying the imaging parameters, and for the multiple captured images I1, the processing regions R are set in different areas depending on the imaging parameters. Therefore, relatively clear images are obtained in the respective processing regions R of the multiple captured images I1. Furthermore, according to the above-described exemplary embodiment, the respective processing regions R of the multiple captured images I1 are image-processed to determine the position of the cutout portion N of the substrate W. That is, the detection of the position of the cutout portion N is performed within the range of the processing regions R the images of which have been acquired under appropriate imaging parameters. As a result, the position of the cutout portion N of the substrate W can be detected with high accuracy, regardless of the location of the cutout portion N in the circumferential direction of the substrate W.

According to the above-described exemplary embodiment, the blower 70 completely covers the substrate W held by the holder 23, when viewed from above, and the imaging device 50 is positioned so that it does not overlap the substrate W held by the holder 23, when viewed from above. In this configuration, the downward flow toward the substrate W by the blower 70 is not obstructed by the imaging device 50. Therefore, the substrate W can be more easily maintained clean by the air flown thereto by the blower 70.

According to the above-described exemplary embodiment, the substrate W is imaged while it is located at the raised position. Therefore, the substrate W is not hidden by the shade of the cup 30, and the entire substrate W can be imaged more reliably.

According to the above-described exemplary embodiment, the positional deviation of the processed substrate W in the circumferential direction is detected based on the position of the cutout portion N of the substrate W before being processed and the position of the cutout portion N of the substrate W after being processed. Therefore, it is possible to detect how much the position of the cutout portion N has deviated before and after the processing of the substrate W.

### Modification Examples

It should be noted that the above-described exemplary embodiments are illustrative in all aspects and are not anyway limiting. The above-described exemplary embodiments may be omitted, replaced and modified in various ways without departing from the scope and the spirit of claims.

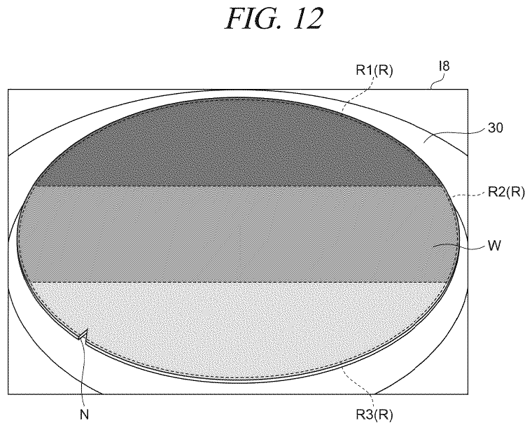

In the above-described exemplary embodiment, the position of the cutout portion N of the substrate W is detected by image-processing the respective processing regions R of the multiple captured images I1 individually. However, as illustrated in FIG. 12, the position of the cutout portion N of the substrate W may be detected by processing a composite image I8 obtained by combining the respective processing regions R of the multiple captured images I1 into one. Here, the generation of the composite image I8 may be performed after the process S11 and before the process S15 in FIG. 7.

### Other Examples

Example 1. An example of a substrate processing apparatus includes a rotating/holding device holding and rotating a substrate having a cutout portion; an imaging device imaging the substrate held by the rotating/holding device; and controller circuitry. The controller is configured to perform: acquiring multiple captured images including an entirety of the substrate with the imaging device by imaging the substrate while the substrate is held stationary by the rotating/holding device, the multiple captured images having a same imaging position with varying imaging parameters; setting, for the multiple captured images, processing regions in different areas depending on the imaging parameters; and detecting a position of the cutout portion of the substrate by image-processing the processing regions of the multiple captured images.

However, the rotating/holding device configured to hold the substrate may have a weakened force for holding the substrate due to deterioration with a lapse of time or the like. In this case, when the substrate rotates accompanied by the processing of the substrate, the substrate may slide in a rotation direction with respect to the rotating/holding device. For this reason, if the rotating/holding device is normal, the position of the cutout portion of the substrate is the same before and after the processing of the substrate, but if the rotating/holding device is deteriorated or the like, the position of the cutout portion of the substrate may be deviated in the rotation direction (circumferential direction) before and after the processing of the substrate. When such a positional deviation occurs, there is a concern that splashing of the processing liquid or the like may occur during the processing of the substrate with the processing liquid, and the substrate processing may not be performed properly. For this reason, the detection of the position of the cutout portion of the substrate is becoming important.

Here, in a method of detecting the cutout portion of the substrate by imaging the substrate with the imaging device, when the imaging device images the entire substrate, since the distance between the imaging device and the substrate is relatively close, a captured image in which a part of the substrate is clearly imaged and another part is unclearly imaged may be obtained. In this case, if the cutout portion of the substrate exists in the unclearly imaged region in the captured image, it may be difficult to detect the cutout portion, since the cutout portion of the substrate is very small with respect to the substrate. Accordingly, according to the apparatus of Example 1, the entire substrate is imaged multiple times at the same imaging position while varying the imaging parameters, and the processing regions are set in the different areas for the multiple captured images depending on the imaging parameters. For this reason, a relatively clear image is obtained in the respective processing regions of the multiple captured images. According to the apparatus of Example 1, the position of the cutout portion of the substrate is detected by image-processing the respective processing regions of the multiple captured images. That is, within the range of each processing region captured under appropriate imaging parameters, the position of the cutout portion is detected. For this reason, it is possible to detect the position of the cutout portion of the substrate with high precision regardless of the position of the cutout portion in the circumferential direction of the substrate.

Example 2. The apparatus of Example 1 further includes at least one illumination device illuminating the substrate when the imaging device is imaging the substrate. The imaging parameters include at least one of luminance of the at least one illumination device, illumination time of the at least one illumination device, a focal position of the imaging device, an ISO sensitivity of the imaging device, or an exposure of the imaging device. In this case, in the respective processing regions of the multiple captured images, a clearer image can be obtained.

Example 3. The apparatus of Example 2 wherein the at least one illumination device includes multiple illumination devices configured to illuminate the substrate from different positions when the imaging device is imaging the substrate. The imaging parameters further include luminance of each of the multiple illumination devices, illumination time of each of the multiple illumination devices, and a position of an illumination device that provides illumination among the multiple illumination devices. In this case, in the respective processing regions of the multiple captured images, a clearer image can be obtained.

Example 4. In the apparatus of Example 2 or 3, the at least one illumination device is composed of an assembly of multiple light sources, and the imaging parameters further include the luminance of the at least one illumination device, the illumination time of the at least one illumination device, and a position of a light source that provides illumination among the multiple light sources in the at least one illumination device. In this case, in the respective processing regions of the multiple captured images, a clearer image can be obtained.

Example 5. In the apparatus of any one of Examples 1 to 4, the detecting of the position of the cutout portion of the substrate includes individually image-processing the processing regions of the multiple captured images to detect the position of the cutout portion of the substrate.

Example 6. In the apparatus of any one of Examples 1 to 4, the detecting of the position of the cutout portion of the substrate includes image-processing a composite image, which is obtained by synthesizing the processing regions of the multiple captured images into one.

Example 7. The apparatus of any one of Examples 1 to 6 further includes a blower disposed above the substrate held by the rotating/holding device, and generating a downward flow toward a top surface of the substrate. The blower covers the entire substrate held by the rotating/holding device, when viewed from above, and the imaging device is disposed at a position that does not overlap the substrate held by the rotating/holding device, when viewed from above. In this case, the downward flow toward the substrate by the blower is not obstructed by the imaging device. Therefore, the substrate can be more easily maintained clean by the air flown thereto by the blower.

Example 8. The apparatus of any one of Examples 1 to 7 further includes a cup surrounding the substrate, which is held by the rotating/holding device, from an outside; and an elevating device configured to move the substrate up and down between a raised position where the substrate is positioned above the cup and a lowered position where the substrate is positioned inside the cup. The acquiring of the multiple captured images includes acquiring the multiple captured images with the imaging device while the substrate is located at the raised position by the elevating device. In this case, the substrate is imaged while it is located at the raised position. Therefore, the substrate is not hidden by the shade of the cup, and the entire substrate can be imaged more reliably.

Example 9. The apparatus of any one of Examples 1 to 8 further includes a supply supplying a processing liquid to the substrate held by the rotating/holding device. The controller circuitry is configured to further perform: supplying, after the acquiring of the multiple captured images, the processing liquid to the substrate while rotating the substrate by controlling the rotating/holding device and the supply; acquiring, after the supplying of the processing liquid, multiple additional captured images including the entirety of the substrate by controlling the imaging device to image the entire substrate multiple times at the same imaging position while varying imaging parameters, with the substrate held stationary by the rotating/holding device; setting, for the multiple additional captured images, processing regions in different areas depending on the imaging parameters; detecting the position of the cutout portion of the substrate by image-processing the processing regions of the multiple additional captured images; and detecting a positional deviation in a circumferential direction of the substrate after being subjected to the supplying of the processing liquid, based on the position of the cutout portion of the substrate detected in the detecting of the position of the cutout portion by image-processing the multiple captured images and the position of the cutout portion of the substrate detected in the detecting of the position of the cutout portion by image-processing the multiple additional captured images. In this case, it is possible to detect how much the position of the cutout portion has deviated before and after the processing of the substrate.

Example 10. An example of a substrate processing method includes acquiring, with an imaging device, multiple captured images including an entire substrate by imaging, with the substrate held stationary by a rotating/holding device, the entire substrate multiple times at a same imaging position while varying imaging parameters; setting, for the multiple captured images, processing regions in different areas depending on the imaging parameters; and detecting a position of a cutout portion of the substrate by image-processing the respective processing regions of the multiple captured images. In this case, the same effect as that of the apparatus of Example 1 is obtained.

Example 11. In the method of Example 10, further comprising illuminating, with at least one illumination device, the substrate when the imaging device is imaging the substrate, the imaging parameters include at least one of luminance of the at least one illumination device, illumination time of the at least one illumination device, a focal position of the imaging device, an ISO sensitivity of the imaging device, or an exposure of the imaging device. In this case, the same effect as that of the apparatus of Example 2 is obtained.

Example 12. In the method of Example 11, the at least one illumination device includes multiple illumination devices and the imaging parameters further include luminance of each of the multiple illumination devices, illumination time of each of the multiple illumination devices, and a position of the illumination device that provides illumination among the multiple illumination devices. In this case, the same effect as that of the apparatus of Example 3 is obtained.

Example 13. In the method of Example 11 or 12, the at least one illumination device is composed of an assembly of multiple light sources, and the imaging parameters further include the luminance of the at least one illumination device, the illumination time of the at least one illumination device, and a position of a light source that provides illumination among the multiple light sources in the at least one illumination device. In this case, the same effect as that of the apparatus of Example 4 is obtained.

Example 14. In the method of any one of Examples 10 to 13, the detecting of the position of the cutout portion of the substrate includes individually image-processing the processing regions of the multiple captured images to detect the position of the cutout portion of the substrate.

Example 15. In the method of any one of Examples 10 to 13, the detecting of the position of the cutout portion of the substrate includes image-processing a composite image, which is obtained by synthesizing the processing regions of the multiple captured images into one, to detect the position of the cutout portion of the substrate.

Example 16. In the method of any one of Examples 10 to 15, further comprising generating, by a blower disposed above the substrate, a downward flow toward a top surface of the substrate, when viewed from above, the entire substrate held by the rotating/holding device is covered by the blower disposed above the substrate, and the imaging device is disposed at a position that does not overlap the substrate held by the rotating/holding device, when viewed from above. In this case, the same effect as that of the apparatus of Example 7 is obtained.

Example 17. In the method of any one of Examples 10 to 16, the acquiring of the multiple captured images includes acquiring the multiple captured images with the imaging device while the substrate is located at a raised position where the substrate is positioned above a cup configured to surround the substrate, which is held by the rotating/holding device, from an outside. In this case, the same effect as that of the apparatus of Example 8 is obtained.

Example 18. The method of any one of Examples 10 to 17 further includes supplying, after the acquiring of the multiple captured images, a processing liquid to the substrate, while rotating the substrate; acquiring, after the supplying of the processing liquid, multiple additional captured images including the entire substrate by imaging the entire substrate multiple times at the same imaging position while varying imaging parameters, with the substrate held by the rotating/holding device being stopped; setting, for the multiple additional captured images, processing regions in different areas depending on the imaging parameters; detecting the position of the cutout portion of the substrate by image-processing the respective processing regions of the multiple additional captured images; and detecting a positional deviation in a circumferential direction of the substrate after being subjected to the supplying of the processing liquid, based on the position of the cutout portion of the substrate detected in the detecting of the position of the cutout portion by image-processing the multiple captured images and the position of the cutout portion of the substrate detected in the detecting of the position of the cutout portion by image-processing the multiple additional captured images. In this case, the same effect as that of the apparatus of Example 9 is obtained.

Example 19. A substrate processing apparatus, comprising a rotating/holding device holding and rotating a substrate having a cutout portion; an imaging device imaging the substrate held by the rotating/holding device; at least one illumination device; and controller circuitry configured to control the imaging device to acquire multiple captured images of the substrate while controlling the rotating/holding device to hold the substrate, the multiple captured images having a same imaging position with varying imaging parameters, control the at least one illumination device to illuminate the substrate during the acquiring the multiple captured images, setting, for the multiple captured images, processing regions in different areas depending on the imaging parameters, and detecting a position of the cutout portion of the substrate by image-processing the processing regions of the multiple captured images, wherein the imaging parameters include at least one of luminance of the at least one illumination device, illumination time of the at least one illumination device, a focal position of the imaging device, an ISO sensitivity of the imaging device, or an exposure of the imaging device.

Example 20. The substrate processing apparatus of Example 19, wherein the at least one illumination device is composed of an assembly of multiple light sources, and the imaging parameters further include the luminance of the at least one illumination device, the illumination time of the at least one illumination device, and a position of a light source that provides illumination among the multiple light sources in the at least one illumination device.

In the substrate processing apparatus and the substrate processing method according to the exemplary embodiment, it is possible to detect the position of the cutout portion of the substrate with high accuracy.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

The present disclosure encompasses various modifications to each of the examples and embodiments discussed herein. According to the disclosure, one or more features described above in one embodiment or example can be equally applied to another embodiment or example described above. The features of one or more embodiments or examples described above can be combined into each of the embodiments or examples described above. Any full or partial combination of one or more embodiment or examples of the disclosure is also part of the disclosure.

We claim:

1. A substrate processing apparatus, comprising:
a rotating/holding device holding and rotating a substrate having a cutout portion;
an imaging device imaging the substrate held by the rotating/holding device; and
controller circuitry configured to perform:
acquiring multiple captured images including an entirety of the substrate with the imaging device by imaging the substrate while the substrate is held stationary by the rotating/holding device, the multiple captured images having a same imaging position with varying imaging parameters,
setting, for the multiple captured images, processing regions in different areas depending on the imaging parameters, and
detecting a position of the cutout portion of the substrate by image-processing the processing regions of the multiple captured images.

2. The substrate processing apparatus of claim 1, further comprising:
at least one illumination device illuminating the substrate when the imaging device is imaging the substrate,
wherein the imaging parameters include at least one of luminance of the at least one illumination device, illumination time of the at least one illumination device, a focal position of the imaging device, an ISO sensitivity of the imaging device, or an exposure of the imaging device.

3. The substrate processing apparatus of claim 2, wherein the at least one illumination device includes multiple illumination devices configured to illuminate the substrate from different positions when the imaging device is imaging the substrate,
wherein the imaging parameters further include luminance of each of the multiple illumination devices, illumination time of each of the multiple illumination devices, and a position of an illumination device that provides illumination among the multiple illumination devices.

4. The substrate processing apparatus of claim 2, wherein
the at least one illumination device is composed of an assembly of multiple light sources, and
the imaging parameters further include the luminance of the at least one illumination device, the illumination time of the at least one illumination device, and a position of a light source that provides illumination among the multiple light sources in the at least one illumination device.

5. The substrate processing apparatus of claim 1, wherein
the detecting of the position of the cutout portion of the substrate comprises individually image-processing the processing regions of the multiple captured images to detect the position of the cutout portion of the substrate.

6. The substrate processing apparatus of claim 1, wherein
the detecting of the position of the cutout portion of the substrate comprises image-processing a composite image, which is obtained by synthesizing the processing regions of the multiple captured images into one.

7. The substrate processing apparatus of claim 1, further comprising:
a blower disposed above the substrate held by the rotating/holding device, the blower generating a downward flow toward a top surface of the substrate,
wherein the blower covers the entire substrate held by the rotating/holding device, when viewed from above, and
the imaging device is disposed at a position that does not overlap the substrate held by the rotating/holding device, when viewed from above.

8. The substrate processing apparatus of claim 1, further comprising:
a cup surrounding the substrate, which is held by the rotating/holding device, from an outside; and
an elevating device moving the substrate up and down between a raised position where the substrate is positioned above the cup and a lowered position where the substrate is positioned inside the cup,
wherein the acquiring of the multiple captured images comprises acquiring the multiple captured images with the imaging device while the substrate is located at the raised position by the elevating device.

9. The substrate processing apparatus of claim 1, further comprising:
a supply supplying a processing liquid to the substrate held by the rotating/holding device,
wherein the controller circuitry is configured to further perform:
supplying, after the acquiring of the multiple captured images, the processing liquid to the substrate while rotating the substrate by controlling the rotating/holding device and the supply;
acquiring, after the supplying of the processing liquid, multiple additional captured images including the entirety of the substrate by controlling the imaging device to image the entire substrate multiple times at the same imaging position while varying imaging parameters, with the substrate held stationary by the rotating/holding device;
setting, for the multiple additional captured images, processing regions in different areas depending on the imaging parameters;
detecting the position of the cutout portion of the substrate by image-processing the processing regions of the multiple additional captured images; and
detecting a positional deviation in a circumferential direction of the substrate after being subjected to the supplying of the processing liquid, based on the position of the cutout portion of the substrate detected in the detecting of the position of the cutout portion by image-processing the multiple captured images and the position of the cutout portion of the substrate detected in the detecting of the position of the cutout portion by image-processing the multiple additional captured images.

10. A substrate processing method, comprising:
acquiring, with an imaging device, multiple captured images including an entire substrate by imaging, with the substrate held stationary by a rotating/holding device, the entire substrate multiple times at a same imaging position while varying imaging parameters;
setting, for the multiple captured images, processing regions in different areas depending on the imaging parameters; and
detecting a position of a cutout portion of the substrate by image-processing the processing regions of the multiple captured images.

11. The substrate processing method of claim 10, further comprising:
illuminating, with at least one illumination device, the substrate when the imaging device is imaging the substrate,
wherein the imaging parameters include at least one of luminance of the at least one illumination device, illumination time of the at least one illumination device, a focal position of the imaging device, an ISO sensitivity of the imaging device, or an exposure of the imaging device.

12. The substrate processing method of claim 11,
wherein the at least one illumination device includes multiple illumination devices, and
the imaging parameters further include luminance of each of the multiple illumination devices, illumination time of each of the multiple illumination devices, and a position of the illumination device that provides illumination among the multiple illumination devices.

13. The substrate processing method of claim 11,
wherein the at least one illumination device is composed of an assembly of multiple light sources, and
the imaging parameters further include the luminance of the at least one illumination device, the illumination time of the at least one illumination device, and a position of a light source that provides illumination among the multiple light sources in the at least one illumination device.

14. The substrate processing method of claim 10,
wherein the detecting of the position of the cutout portion of the substrate comprises individually image-processing the processing regions of the multiple captured images to detect the position of the cutout portion of the substrate.

15. The substrate processing method of claim 10,
wherein the detecting of the position of the cutout portion of the substrate comprises image-processing a composite image, which is obtained by synthesizing the processing regions of the multiple captured images into one, to detect the position of the cutout portion of the substrate.

16. The substrate processing method of claim 10, further comprising:
generating, by a blower disposed above the substrate, a downward flow toward a top surface of the substrate, when viewed from above,
wherein the entire substrate held by the rotating/holding device is covered by the blower disposed above the substrate, and
the imaging device is disposed at a position that does not overlap the substrate held by the rotating/holding device, when viewed from above.

17. The substrate processing method of claim 10,
wherein the acquiring of the multiple captured images comprises acquiring the multiple captured images with the imaging device while the substrate is located at a raised position where the substrate is positioned above a cup configured to surround the substrate, which is held by the rotating/holding device, from an outside.

18. The substrate processing method of claim 10, further comprising:
supplying, after the acquiring of the multiple captured images, a processing liquid to the substrate, while rotating the substrate;
acquiring, after the supplying of the processing liquid, multiple additional captured images including the entire substrate by imaging the entire substrate multiple times at the same imaging position while varying imaging parameters, with the substrate held by the rotating/holding device being stopped;
setting, for the multiple additional captured images, processing regions in different areas depending on the imaging parameters;
detecting the position of the cutout portion of the substrate by image-processing the respective processing regions of the multiple additional captured images; and
detecting a positional deviation in a circumferential direction of the substrate after being subjected to the supplying of the processing liquid, based on the position of the cutout portion of the substrate detected in the detecting of the position of the cutout portion by image-processing the multiple captured images and the position of the cutout portion of the substrate detected in the detecting of the position of the cutout portion by image-processing the multiple additional captured images.

19. A substrate processing apparatus, comprising:
a rotating/holding device holding and rotating a substrate having a cutout portion;
an imaging device imaging the substrate held by the rotating/holding device;
at least one illumination device; and
controller circuitry configured to: control the imaging device to acquire multiple captured images of the substrate while controlling the rotating/holding device to hold the substrate, the multiple captured images having a same imaging position with varying imaging parameters,
control the at least one illumination device to illuminate the substrate during the acquiring the multiple captured images,
setting, for the multiple captured images, processing regions in different areas depending on the imaging parameters, and
detecting a position of the cutout portion of the substrate by image-processing the processing regions of the multiple captured images,
wherein the imaging parameters include at least one of luminance of the at least one illumination device, illumination time of the at least one illumination device, a focal position of the imaging device, an ISO sensitivity of the imaging device, or an exposure of the imaging device.

20. The substrate processing apparatus of claim 19, wherein
the at least one illumination device is composed of an assembly of multiple light sources, and
the imaging parameters further include the luminance of the at least one illumination device, the illumination time of the at least one illumination device, and a position of a light source that provides illumination among the multiple light sources in the at least one illumination device.
